(19) United States
(12) Patent Application Publication
(10) Pub. No.: US 2025/0373957 A1
(43) Pub. Date: Dec. 4, 2025

(54) PHOTOELECTRIC CONVERSION DEVICE, PHOTOELECTRIC CONVERSION SYSTEM, AND MOVABLE OBJECT

(71) Applicant: CANON KABUSHIKI KAISHA, Tokyo (JP)

(72) Inventors: KOICHIRO IWATA, Kanagawa (JP); KOHICHI NAKAMURA, Kanagawa (JP); MASANOBU OHMURA, Kanagawa (JP)

(21) Appl. No.: 19/221,286

(22) Filed: May 28, 2025

(30) Foreign Application Priority Data
Jun. 3, 2024 (JP) 2024-090291

(51) Int. Cl. H04N 25/771; H04N 25/532; H04N 25/76; H04N 25/78; H10F 39/00

(52) U.S. Cl. CPC H04N 25/771; H04N 25/532; H04N 25/7795; H04N 25/78; H10F 39/8053; H10F 39/811

(57) ABSTRACT

A photoelectric conversion device includes a plurality of pixels including a first pixel and a second pixel, wherein each of the plurality of pixels includes a first semiconductor layer including a photoelectric conversion unit and a first readout circuit, and a second semiconductor layer including a memory and an output circuit, the first semiconductor layer and the second semiconductor layer being layered, wherein the first readout circuit of the first pixel includes a first amplification transistor, wherein the first readout circuit of the second pixel includes a second amplification transistor, wherein the first amplification transistor is connected to a first current source via a first switch, wherein the second amplification transistor is connected to the first current source via a second switch, and wherein the first amplification transistor and the second amplification transistor share the first current source.

### BACKGROUND OF THE DISCLOSURE

### Field of the Disclosure

The present disclosure relates to a photoelectric conversion device, a photoelectric conversion system, and a movable object.

### Description of the Related Art

In a photoelectric conversion device, there is proposed a technique for performing a global electronic shutter operation that performs resetting of a photoelectric conversion element arranged in each of a plurality of pixels and reading out charges from the photoelectric conversion element at a time. Japanese Patent Application Laid-Open No. 2022-051548 discusses an image sensor provided with a voltage holding type global electronic shutter function that converts signal charges into voltages and holds the converted voltages.

An image capturing apparatus provided with the voltage holding type global electronic shutter function discussed in Japanese Patent Application Laid-Open No. 2022-051548 has a restriction on a pixel layout because the image capturing apparatus has many components per unit pixel.

### SUMMARY OF THE DISCLOSURE

According to an aspect of the present disclosure, a photoelectric conversion device includes a plurality of pixels including a first pixel and a second pixel, wherein each of the plurality of pixels includes a first semiconductor layer including a photoelectric conversion unit, and a first readout circuit configured to read out a signal obtained based on photoelectric conversion by the photoelectric conversion unit, and a second semiconductor layer including a memory configured to hold a voltage corresponding to the signal, and an output circuit configured to output the voltage held in the memory, the first semiconductor layer and the second semiconductor layer being layered, wherein the first readout circuit of the first pixel includes a first amplification transistor, wherein the first readout circuit of the second pixel includes a second amplification transistor, wherein the first amplification transistor is connected to a first current source via a first switch, wherein the second amplification transistor is connected to the first current source via a second switch, and wherein the first amplification transistor and the second amplification transistor share the first current source.

Further features of the present disclosure will become apparent from the following description of exemplary embodiments with reference to the attached drawings.

### BRIEF DESCRIPTION OF THE DRAWINGS

FIG. 1 is a block diagram schematically illustrating an entire configuration of a photoelectric conversion device.

FIG. 2 is a diagram illustrating a layered structure of a substrate of the photoelectric conversion device.

FIG. 3 is a circuit diagram of pixels, pixel memories, and a column signal processing circuit of the photoelectric conversion device according to a first exemplary embodiment.

FIG. 4 is a driving timing chart illustrating one frame of the photoelectric conversion device according to the first exemplary embodiment.

FIGS. 5A, 5B, and 5C are driving timing charts of the photoelectric conversion device according to the first exemplary embodiment.

FIG. 6 is a plan view illustrating positions of joint portions and a current source in the photoelectric conversion device according to the first exemplary embodiment.

FIGS. 7A and 7B are a circuit diagram of pixels, pixel memories, and a column signal processing circuit of the photoelectric conversion device according to a second exemplary embodiment.

FIG. 8 is a driving timing chart illustrating one frame of the photoelectric conversion device according to the second exemplary embodiment.

FIGS. 9A, 9B, and 9C are driving timing charts of the photoelectric conversion device according to the second exemplary embodiment.

FIGS. 10A and 10B are plan views each illustrating positions of joint portions and a current source in the photoelectric conversion device according to the second exemplary embodiment.

FIG. 11 is a circuit diagram of pixels, pixel memories, and a column signal processing circuit of the photoelectric conversion device according to a third exemplary embodiment.

FIG. 12 is a driving timing chart of the photoelectric conversion device according to the third exemplary embodiment.

FIG. 13 is a circuit diagram of pixels, pixel memories, and a column signal processing circuit of the photoelectric conversion device according to the third exemplary embodiment.

FIGS. 14A, 14B, and 14C are functional block diagrams of a photoelectric conversion system according to a fourth exemplary embodiment.

### DESCRIPTION OF THE EMBODIMENTS

The exemplary embodiments described below are intended to embody the technical idea of the present disclosure, and are not intended to limit the present disclosure. Sizes and positional relationships of members illustrated in the drawings may be exaggerated for clarity of explanation. In the following description, identical components are denoted by the same reference numerals, and the description thereof may be omitted.

Hereinafter, the exemplary embodiments of the present disclosure will be described in detail with reference to the drawings. In the following description, terms indicating specific directions and positions (for example, “up”, “down”, “right”, “left”, and other terms including these terms) are used as necessary. The use of these terms is intended to facilitate understanding of the exemplary embodiments with reference to the drawings, and the technical scope of the present disclosure is not limited by the meanings of these terms.

In the present specification, the plan view refers to a view from a direction perpendicular to a light incident surface of a semiconductor layer. The cross-sectional view refers to viewing a cross section perpendicular to the light incident surface of the semiconductor layer. In the case where the light incident surface of the semiconductor layer is a rough surface when viewed microscopically, the plan view is defined with reference to the light incident surface of the semiconductor layer when viewed macroscopically.

In the following exemplary embodiments, connections between elements of a circuit may be described. In such a case, even when another element is interposed between the elements of interest, the elements of interest are regarded as being connected to each other unless otherwise specified. For example, it is assumed that an element A is connected to one node of a capacitor C having a plurality of nodes and an element B is connected to the other node. Even in such a case, the element A and the element B are treated as being connected unless otherwise specified.

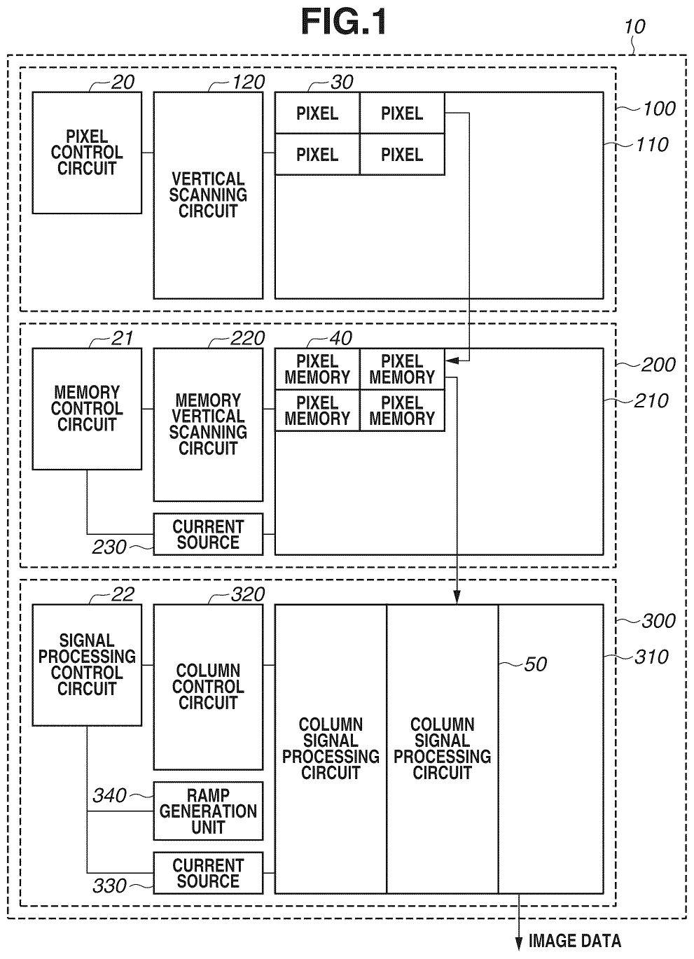

With reference to FIGS. 1 to 6, a photoelectric conversion device according to a first exemplary embodiment will be described.

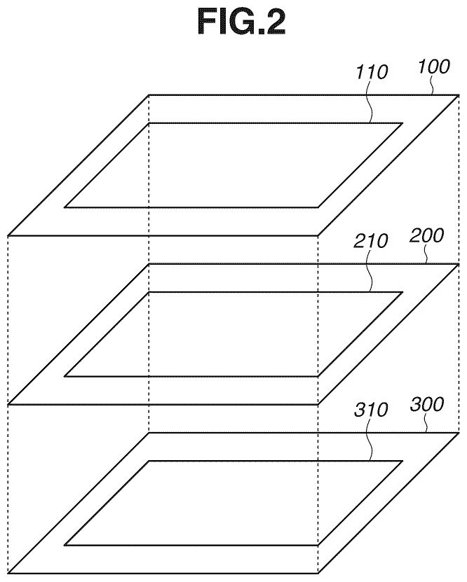

FIG. 1 is a block diagram schematically illustrating an exemplary embodiment of a photoelectric conversion device. A photoelectric conversion device 10 has a layered structure in which a pixel chip 100 (first chip), a memory chip 200 (second chip), and a signal processing chip 300 (third chip) are layered as illustrated in FIG. 2. Signals can be exchanged between the chips by wiring lines, provided on the chips, being joined with each other.

The pixel chip 100 illustrated in FIGS. 1 and 2 includes a first semiconductor layer and a first wiring structure, and is provided with a pixel region 110, a vertical scanning circuit 120, and a pixel control circuit 20. The pixel region 110 is a region in which pixels 30, each of which is a unit pixel, are arranged in an array arrangement in row and column directions. Each of the pixels 30 includes photoelectric conversion elements (e.g., photodiodes) each outputting a pixel signal (signal voltage) corresponding to a light quantity of incident light. An optical black pixel in which a photoelectric conversion portion is shielded from light, a dummy pixel outputting no signals, and the like may be arranged in the pixel region 110 in addition to effective pixels each outputting the pixel signal corresponding to the light quantity of the incident light. Further, the number of rows and the number of columns of a pixel array arranged in the pixel region 110 are not particularly limited. The pixel control circuit 20 is a logic circuit for generating timings for operating the pixels 30, and outputs driving pulses for the pixels 30 to the vertical scanning circuit 120.

The vertical scanning circuit 120 includes a driver for driving the pixels 30 for each row.

The memory chip 200 includes a second semiconductor layer and a second wiring structure, and is provided with a memory region 210, a memory vertical scanning circuit 220, a current source 230, and a memory control circuit 21. The memory region 210 is a region in which pixel memories 40 are arranged in an array arrangement in row and column directions. Each of the pixel memories 40 has a function of holding a signal voltage output from the corresponding pixel 30. The number of arranged pixels 30 and the number of arranged pixel memories 40 do not necessarily need to be the same. For example, the pixel memory 40 do not need to be arranged for the dummy pixel that does not output a signal. Further, a dummy pixel memory that does not output a signal may be arranged for the dummy pixel.

The current source 230 supplies a reference current to each of the pixel memories 40. The memory control circuit 21 includes a logic circuit that generates timings for operating the pixel memories 40 and controls circuits arranged around the pixel region 110, such as the current source 230. Drive pulses output from the memory control circuit 21 are input to the memory vertical scanning circuit 220. The memory vertical scanning circuit 220 includes a driver for driving the pixel memories 40 for each row.

The signal processing chip 300 includes a third semiconductor layer and a third wiring structure, and is provided with a signal processing unit 310, a column control circuit 320, a ramp generation unit 340, a current source 330, and a signal processing control circuit 22. In the signal processing unit 310, column signal processing circuits 50 serving as output circuits are arranged in an array arrangement in the row direction. Each of the column signal processing circuits 50 has a function of performing analog-to-digital (AD) conversion on the signal voltage output from each of the pixel memories 40 based on a reference voltage generated by the ramp generation unit 340, and of outputting an AD converted digital signal as image data outside the signal processing chip 300.

In the present exemplary embodiment, a ramp type AD conversion method is used, but the AD conversion method is not limited to a specific method. Further, each of the column signal processing circuits 50 may have a function of performing digital processing on the image data, such as noise reduction processing. The current source 330 supplies a reference current to each of the column signal processing circuits 50. The signal processing control circuit 22 includes a logic circuit that generates timings for operating the column signal processing circuits 50, and performs function settings of the ramp generation unit 340 and the current source 330. Drive pulses output from the signal processing control circuit 22 are input to the column control circuit 320. The column control circuit 320 includes a driver for outputting drive pulses to the column signal processing circuits 50.

The pixel chip 100, the memory chip 200, and the signal processing chip 300 are layered as illustrated in FIG. 2, to constitute the photoelectric conversion device 10. The signals generated by the pixel chip 100 are output to the outside of the photoelectric conversion device 10 through the wiring lines connected between the pixel chip 100 and the memory chip 200, and the wiring lines of the signal processing chip 300.

The photoelectric conversion device 10 according to the present exemplary embodiment is a photoelectric conversion device that performs what is called a voltage holding type global electronic shutter operation.

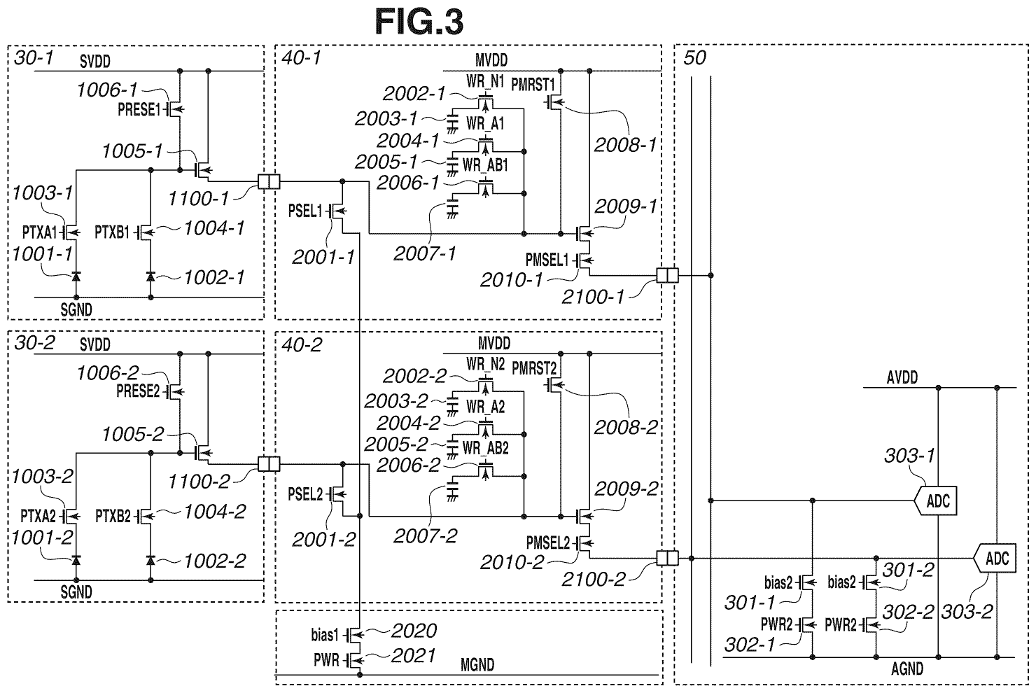

FIG. 3 is a circuit diagram of the pixels 30, the pixel memories 40, and the column signal processing circuit 50 according to the present exemplary embodiment.

In the present exemplary embodiment, the pixels 30, the pixel memories 40, and the column signal processing circuits 50 are arranged in respective different semiconductor layers. Each of the pixels 30 has a power source SVDD and a ground SGND, each of the pixel memories 40 has a power source MVDD and a ground MGND, and the column signal processing circuit 50 has a power source AVDD and a ground AGND.

In the photoelectric conversion device 10 according to the present exemplary embodiment, two amplification transistors respectively corresponding to a first pixel 30-1 and a second pixel 30-2 included in the pixels 30 share one current source. The first pixel 30-1 is connected with the first pixel memory 40-1 via a first joint portion 1100-1, and the second pixel 30-2 is connected with the second pixel memory 40-2 via a second joint portion 1100-2. The first pixel memory 40-1 is connected with the column signal processing circuit 50 serving as a first readout circuit via a first joint portion 2100-1. The second pixel memory 40-2 is connected with the column signal processing circuit 50 serving as a second readout circuit via a second joint portion 2100-2.

Now, the first pixel 30-1, which is one of the pixels 30, will be described.

The first pixel 30-1 includes a photodiode (PD) 1001-1, a PD 1002-1, a transfer transistor 1003-1, a transfer transistor 1004-1, an amplification transistor 1005-1, and a reset transistor 1006-1.

The photoelectric conversion device 10 according to the present exemplary embodiment is a photoelectric conversion device in which the PD 1001-1 and the PD 1002-1 constitute one pixel, and signals of the PD 1001-1 and the PD 1002-1 are used for phase difference detection, usable for what is called a phase difference auto-focus (PDAF). Further, the photoelectric conversion device 10 according to the present exemplary embodiment is an image capturing device (herein, a complementary metal-oxide semiconductor (CMOS) sensor) in which the signal of at least one of the PD 1001-1 and the PD 1002-1 are used for image forming.

One terminal of the PD 1001-1 is connected with the source of the transfer transistor 1003-1, and one terminal of the PD 1002-1 is connected with the source of the transfer transistor 1004-1.

The drains of the transfer transistor 1003-1 and the transfer transistor 1004-1 are connected with the gate of the amplification transistor 1005-1. A node connected with the gate of the amplification transistor 1005-1 operates as a floating diffusion when charges photoelectrically converted by the PD 1001-1 and the PD 1002-1 are read out.

The drain of the amplification transistor 1005-1 is connected to the power source SVDD. The source of the amplification transistor 1005-1 is connected with the first pixel memory 40-1 via the first joint portion 1100-1. The reset transistor 1006-1 is connected in series between the gate of the amplification transistor 1005-1 and the power source SVDD.

Components of the second pixel 30-2 may be understood by replacing the suffix “-1” attached to the reference numeral of each of the components of the first pixel 30-1 described above with the suffix “-2”, and thus descriptions thereof are omitted.

Next, the first pixel memory 40-1, which is one of the pixel memories 40, will be described.

The first pixel memory 40-1 includes a signal holding unit 2003-1, a signal holding unit 2005-1, and a signal holding unit 2007-1. The signal holding unit 2003-1 is connected to a switch 2002-1, the signal holding unit 2005-1 is connected to a switch 2004-1, and the signal holding unit 2007-1 is connected to a switch 2006-1. The first pixel memory 40-1 further includes a selection transistor 2001-1, a reset transistor 2008-1, a first amplification transistor 2009-1, and a selection transistor 2010-1.

The source of the amplification transistor 1005-1 in the first pixel 30-1 is connected with the drain of the selection transistor 2001-1 (first switch) via the first joint portion 1100-1. In this way, the source of the amplification transistor 1005-1 is connected to the drain of a current source 2020 via the selection transistor 2001-1.

In the present exemplary embodiment, it is possible to control the selection transistors so as to selectively obtain any one of a state in which the selection transistor 2001-1 is ON and a selection transistor 2001-2 (second switch) is OFF, a state in which the selection transistor 2001-1 is OFF and the selection transistor 2001-2 is ON, and a state in which both of the selection transistors 2001-1 and 2001-2 are OFF.

One terminal of the signal holding unit 2003-1 is connected to the ground MGND, and the other terminal thereof is connected to the source of the switch 2002-1. The drain of the switch 2002-1 is connected to the gate of the first amplification transistor 2009-1.

In a similar manner, one terminal of the signal holding unit 2005-1 is connected to the ground MGND, and the other terminal thereof is connected to the source of the switch 2004-1. The drain of the switch 2004-1 is connected to the gate of the first amplification transistor 2009-1.

One terminal of the signal holding unit 2007-1 is connected to the ground MGND, and the other terminal thereof is connected to the source of the switch 2006-1. The drain of the switch 2006-1 is connected to the gate of the first amplification transistor 2009-1.

Each of the signal holding units 2003-1, 2005-1, and 2007-1 only needs to be an element with a function of holding a signal, and examples thereof include a dynamic random access memory (DRAM) and a metal-insulator-metal (MIM) capacitor.

A signal WR_N1 is input to the gate of the switch 2002-1, and a signal WR_A1 is input to the gate of the switch 2004-1. A signal WR_AB1 is input to the gate of the switch 2006-1. When the switch 2002-1 is turned ON by the signal WR_N1, a signal voltage output from the amplification transistor 1005-1 is written into the signal holding unit 2003-1. In a similar manner, a signal voltage can be written into the signal holding unit 2005-1 in response to the signal WR_A1, and a signal voltage can be written into the signal holding unit 20076-1 in response to the signal WR_AB1.

The drain of the reset transistor 2008-1 is connected with a power source wiring line for supplying the power source MVDD as a reference power source. The source of the reset transistor 2008-1 is connected to the gate of the first amplification transistor 2009-1. When a signal PMRST1 is high (Hi), the gate of the first amplification transistor 2009-1 is reset.

Components of the second pixel memory 40-2 may be understood by replacing the suffix “-1” attached to the reference numeral of each of the components of the first pixel memory 40-1 described above with the suffix “-2”, and thus descriptions thereof are omitted.

Here, the source of the selection transistor 2001-1 (first switch) in the first pixel memory 40-1 and the source of the selection transistor 2001-2 (second switch) in the second pixel memory 40-2 are connected with the drain of the current source 2020. A switch 2021 is connected in series between the current source 2020 and the ground MGND.

A voltage bias 1 is supplied to the gate of the current source 2020, and a voltage PWR is supplied to the gate of the switch 2021. The voltage bias 1 can be freely set depending on a value of a current desired to be passed through the amplification transistor 1005-1 and an amplification transistor 1005-2.

In general, in a configuration of a voltage holding type global electronic shutter, to read out the signals of the pixels 30, a dedicated current source is provided for an amplification transistor in each pixel. In the present exemplary embodiment, the amplification transistor 1005-1 and the amplification transistor 1005-2 in the two pixels of the first pixel 30-1 and the second pixel 30-2 share the one current source 2020. With this configuration, the number of the elements (components) included in the photoelectric conversion device 10 can be reduced, and the restriction on the layout of the pixels can be reduced. With the restriction on the layout of the pixels being reduced, a pixel area can be formed smaller, which is advantageous.

The column signal processing circuit 50 includes an analog-to-digital converter (ADC) 303-1 and an ADC 303-2 as AD converters. To an input terminal of the ADC 303-1, the drain of a current source 301-1 and the source of the selection transistor 2010-1 of the first pixel memory 40-1 are connected via the first joint portion 2100-1. Between the source of the current source 301-1 and the ground AGND, a switch 302-1 is connected in series.

To an input terminal of the ADC 303-2, the drain of a current source 301-2, and the source of a selection transistor 2010-2 of the second pixel memory 40-2 is connected via the second joint portion 2100-2.

Between the source of the current source 301-2 and the ground AGND, a switch 302-2 is connected in series.

A voltage bias 2 is supplied to the gate of the current source 301-1 and the gate of a current source 301-2. The voltage bias 2 can be freely set depending on a value of a current desired to be passed through the first amplification transistor 2009-1 and a second amplification transistor 2009-2.

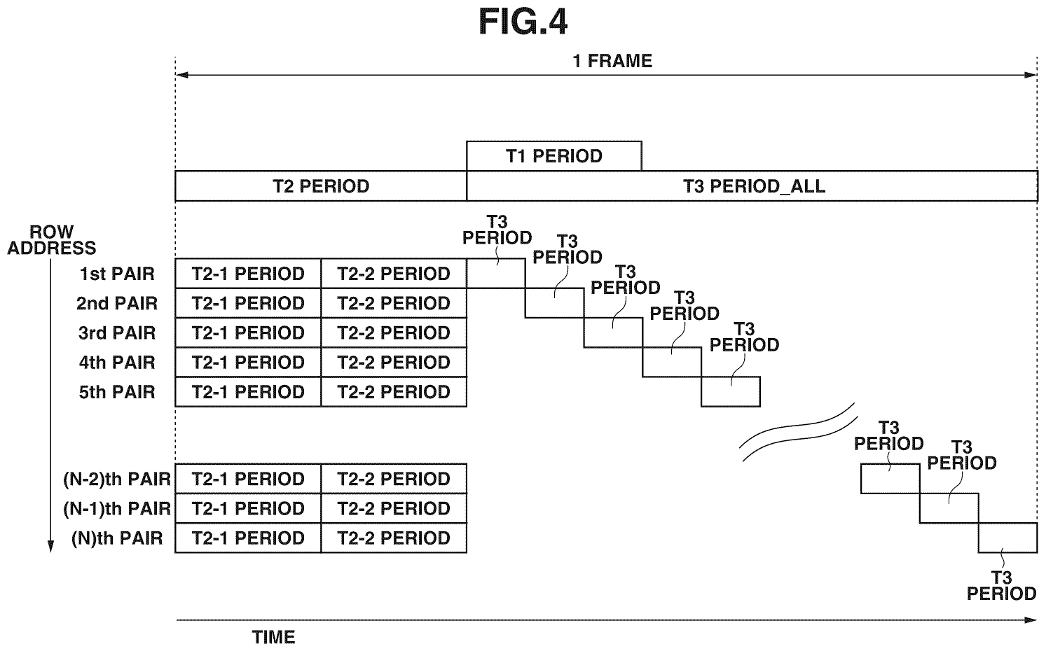

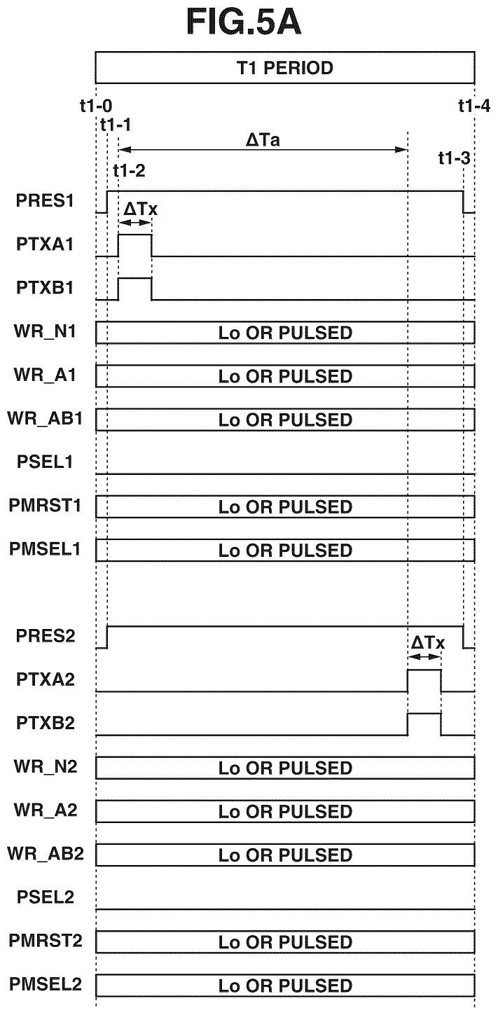

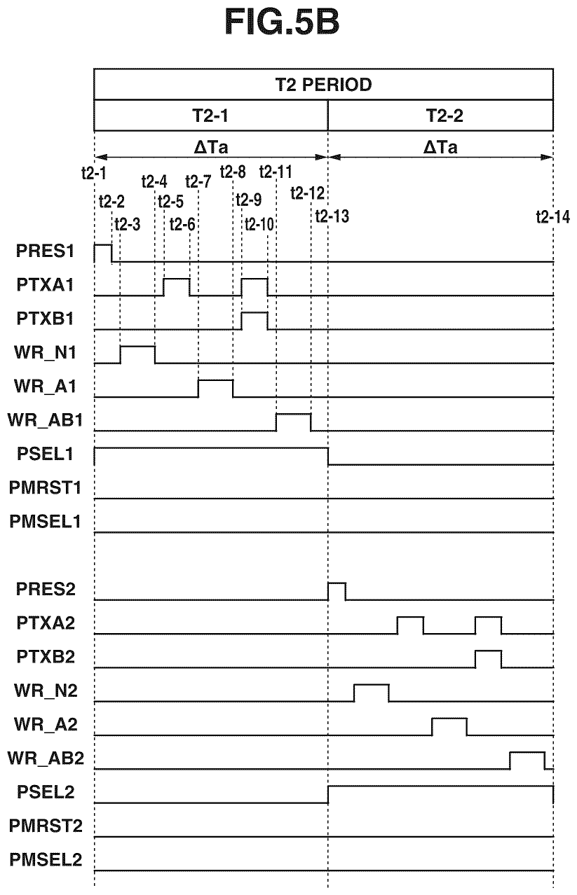

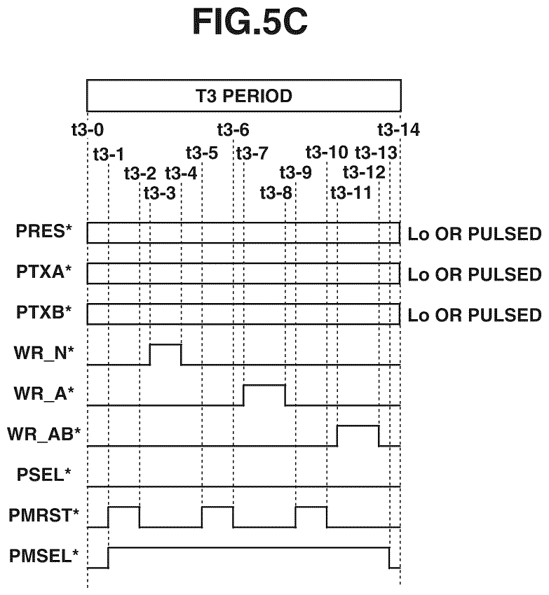

Next, with reference to FIGS. 4, 5A, 5B, and 5C, operations of the pixels 30, the pixel memories 40, and the column signal processing circuit 50 will be described.

As illustrated in FIG. 4, in the present exemplary embodiment, one frame is constituted of a T1 period, a T2 period, and a T3 period_all. The T1 period is a period for resetting each photodiode, and the T2 period is a period for writing a signal output from each pixel in a memory. A T3 period is a period for reading out a signal from the memory to the column signal processing circuit 50, and the T3 period_all is a collective term for a plurality of T3 periods.

In the present exemplary embodiment, during the T3 period, reading of a signal from one of the pixel memories 40 to the corresponding one of the column signal processing circuits 50 is performed for two pixels arranged in a vertical direction (column direction) at a time. Thus, in a case where the number of rows of the pixels 30 arranged in the pixel array is N, the T3 period is repeated N/2 times during the T3 period_all. In addition, in a case where two pixels arranged in a horizontal direction (row direction) share a reading period, the T3 period is repeated N times. In this case, the number of times of repeating the T3 period can be reduced by increasing the number of pixels 30 in a group (pair) read out from each of the pixel memories 40 to the corresponding column signal processing circuit 50 at a time.

In FIG. 4, the T1 period and the T3 period_all overlap, but, for example, operations described as operations in the T3 period may be halted during operations described as operations in the T1 period.

With reference to FIG. 5A, reset operations for the PD 1001-1, the PD 1002-1, a PD 1001-2, and a PD 1002-2 performed in the T1 period from a time t1-0 to a time t1-4 will be described.

During the period from a time t1-1 to a time t1-3, signals PRES1 and PRES2 are high (Hi). The signal PRES1 is a control signal supplied to the gate of the reset transistor 1006-1, and the signal PRES2 is a control signal supplied to the gate of a reset transistor 1006-2. When the signal PRES1 is Hi, the reset transistor 1006-1 is turned ON, and when the signal PRES1 is low (Lo), the reset transistor 1006-1 is turned OFF. Similarly, when the signal PRES2 is Hi, the reset transistor 1006-2 is turned ON, and when the signal PRES2 is Lo, the reset transistor 1006-2 is turned OFF.

At a time t1-2, signals PTXA1 and PTXB1 become Hi from Lo. The signal PTXA1 is a control signal supplied to the gate of the transfer transistor 1003-1, and the signal PTXB1 is a control signal supplied to the gate of the transfer transistor 1004-1. When the signal PTXA1 is Hi, the transfer transistor 1003-1 is turned ON, and when the signal PTXA1 is Lo, the transfer transistor 1003-1 is turned OFF. When the signal PTXB1 is Hi, the transfer transistor 1004-1 is turned ON, and when the signal PTXB1 is Lo, the transfer transistor 1004-1 is turned OFF.

During a period ΔTx from the time t1-2, the signals PTXA1 and PTXB1 are kept Hi. During that period, the reset transistor 1006-1, the transfer transistor 1003-1, and the transfer transistor 1004-1 are turned ON to reset the PD 1001-1 and the PD 1002-1.

After the period ΔTx has elapsed, the signals PTXA1 and PTXB1 become Lo, and the transfer transistor 1003-1 and the transfer transistor 1004-1 are turned OFF to end resetting the PD 1001-1 and the PD 1002-1.

After a period ΔTa has elapsed from the time t1-2, signals PTXA2 and PTXB2 become Hi, and then are kept Hi during the period ΔTx.

The signal PTXA2 is a control signal input to the gate of a transfer transistor 1003-2 of the second pixel 30-2, and the signal PTXB2 is a control signal input to the gate of a transfer transistor 1004-2. Since during the period in which the signals PTXA2 and PTXB2 are Hi, the signal PRES2 is also Hi, the PD 1001-2 and the PD 1002-2 are reset.

At the time t1-3, since the signal PRES1 and the signal PRES2 become Lo, and the reset transistor 1006-1 and the reset transistor 1006-2 are turned OFF, the gate of the amplification transistor 1005-1 and the gate of the amplification transistor 1005-2 each becomes a floating state.

During the T1 period illustrated in FIG. 5A, signals PSEL1 and PSEL2 are fixed to Lo.

The signal WR_N1, a signal WR_N2, the signal WR_A1, a signal WR_A2, the signal WR_AB1, a signal WR_AB2, the signal PMRST1, a signal PMRST2, a signal PMSEL1, and a signal PMSEL2 are fixed to Lo or pulsed.

Next, with reference to FIG. 5B, operations of writing the signals output from the respective pixels 30 in the corresponding pixel memories 40 will be described. A time period from a time t2-1 to a time t2-13 in FIG. 5B is referred to as a T2-1 period, and a time period from the time t2-13 to a time t2-14 is referred to as a T2-2 period. The T2-1 period and the T2-2 period are collectively referred to as the T2 period. In the T2 period, a reading operation of reading an output signal of the first pixel 30-1 into the first pixel memory 40-1, and a reading operation of reading an output signal of the second pixel 30-2 into the second pixel memory 40-2 can be exclusively performed by sequentially performing driving in the T2-1 period and driving in the T2-2 period.

The reading operation of reading the output signal of the first pixel 30-1 into the first pixel memory 40-1 in the T2-1 period will be described.

During the period from the time t2-1 to the time t2-13, the signal PSEL1 is Hi, and the signal PSEL2 is Lo.

During the period from the time t2-1 to the time t2-13, the source of the amplification transistor 1005-1 of the first pixel 30-1 is connected to the current source 2020 via the selection transistor 2001-1.

While not illustrated in FIG. 5B, the switch 2021 is turned ON when the signals of the first pixel 30-1 and the second pixel 30-2 are read out. In other words, the switch 2021 may be turned ON when the current source 2020 is used as a current source load for the amplification transistor 1005-1 or the amplification transistor 1005-2, and the switch 2021 may be turned OFF in other periods.

At the time t2-1, the signal PRES1 becomes Hi, the reset transistor 1006-1 is turned ON, and the gate of the amplification transistor 1005-1 is reset with the power source SVDD.

At a time t2-2, the signal PRES1 becomes Lo to end resetting the gate of the amplification transistor 1005-1.

During a period from a time t2-3 to a time t2-4, the signal WR_N1 is Hi. The signal WR_N1 is a control signal for the switch 2002-1, and during this period, a voltage obtained by resetting the gate of the amplification transistor 1005-1 is written in the signal holding unit 2003-1 via the amplification transistor 1005-1. This signal (voltage) is referred to as an N signal.

During a period from a time t2-5 to a time t2-6, the signal PTXA1 is Hi, and the transfer transistor 1003-1 is turned ON to read out the charge photoelectrically converted by the PD 1001-1 to the gate of the amplification transistor 1005-1.

During a period from a time t2-7 to a time t2-8, the signal WR_A1 is Hi. The signal WR_A1 is a control signal for the switch 2004-1. The charge of the PD 1001-1 read out to the gate of the amplification transistor 1005-1 during the period from the time t2-5 to the time t2-6 is converted into a voltage by the amplification transistor 1005-1, and written in the signal holding unit 2005-1. The written signal (voltage) is referred to as an SA signal.

During a period from a time t2-9 to a time t2-10, the signals PTXA1 and PTXB1 are Hi. The transfer transistor 1003-1 and the transfer transistor 1004-1 are turned ON, and the charges photoelectrically converted by the PD 1001-1 and the PD 1002-1 are read out to the gate of the amplification transistor 1005-1.

During a period from a time t2-11 to a time t2-12, the signal WR_AB1 is Hi. The signal WR_AB1 is a control signal for the switch 2006-1. The charges of the PD 1001-1 and the PD 1002-1 read out to the gate of the amplification transistor 1005-1 during the period from the time t2-9 to the time t2-10 is written in the signal holding unit 2007-1 via the amplification transistor 1005-1.

This signal is referred to as an SAB signal.

At the time t2-13, the signal PSEL1 becomes Lo, and the signal PSEL2 becomes Hi. With this operation, the selection transistor 2001-1 is turned OFF to electrically cut off an electrical path between the amplification transistor 1005-1 of the first pixel 30-1 and the current source 2020. On the other hand, when the selection transistor 2001-2 is turned ON, the amplification transistor 1005-2 of the second pixel 30-2 and the current source 2020 are connected.

During a subsequent period from the time t2-13 to the time t2-14, an operation of writing the signal of the second pixel 30-2 in the second pixel memory 40-2 is performed in a similar manner to the writing operation of the signal of the first pixel 30-1 in the first pixel memory.

At this time, both of the lengths of the T2-1 period and the T2-2 period are the period ΔTa.

To match charge accumulation periods of the photodiodes of the first pixel 30-1 and the second pixel 30-2, in the T1 period, a timing at which the signals PTXA2 and PTXB2 operate is the period ΔTa after the timing at which the signals PTXA1 and PTXB1 operate. In the T2 period, a timing at which the signal of the second pixel 30-2 is written in the second pixel memory 40-2 is shifted by the period ΔTa from a timing at which the signal of the first pixel 30-1 is written in the first pixel memory 40-1.

In a case where a photodiode reset period of the first pixel 30-1 and a photodiode reset period of the second pixel 30-2 are not shifted in the T1 period, a shift generated in the accumulation period may be corrected in the chip or outside the chip.

During the T2 period, the signal PMRST1, the signal PMRST2, the signal PMSEL1, and the signal PMSEL2 are Lo.

Next, with reference to FIG. 5C, a readout method of a signal from one of the pixel memories 40 to the corresponding column signal processing circuit 50 will be described. A period from a time t3-0 to a time t3-14 in FIG. 5C is referred to as the T3 period. The signals PRES1, PRES2, PTXA1, PTXA2, PTXB1, and PTXB2 are Lo or pulsed (PRES1 and PRES2, PTXA1 and PTXA2, and PTXB1 and PTXB2 are collectively illustrated as PRES*, PTXA*, and PTXB* in FIG. 5C, respectively).

During a period from a time t3-1 to a time t3-13, the signals PMSEL1 and PMSEL2 (collectively illustrated as PMSEL* in FIG. 5C) are Hi. With this operation, the selection transistor 2010-1 and the selection transistor 2010-2 are turned ON. The source of the first amplification transistor 2009-1 of the first pixel memory 40-1 is connected with the current source 301-1, and the source of the second amplification transistor 2009-2 of the second pixel memory 40-2 is connected with the current source 301-2.

The switch 302-1 and the switch 302-2 are controlled by a control signal PWR2 (not illustrated in FIG. 5C).

The control signal PWR2 is Hi during the T3 period, and is any value during other periods.

During a period from the time t3-1 to a time t3-2, the signals PMRST1 and PMRST2 (collectively illustrated as PMRST* in FIG. 5C) are Hi. With this operation, the reset transistor 2008-1 and a reset transistor 2008-2 are turned ON to reset the gate of the first amplification transistor 2009-1 and the gate of the second amplification transistor 2009-2 with the power source MVDD.

During a period from a time t3-3 to a time t3-4, the signal WR_N1 and the signal WR_N2 (collectively illustrated as WR_N* in FIG. 5C) are Hi, and the switch 2002-1 and a switch 2002-2 are turned ON. The N signal of the first pixel 30-1 held in the signal holding unit 2003-1 is read out to the ADC 303-1 via the first amplification transistor 2009-1. The N signal of the second pixel 30-2 held in a signal holding unit 2003-2 is read out to the ADC 303-2 via the second amplification transistor 2009-2. In a period from the time t3-4 to a time t3-5, the N signals are respectively AD-converted by the ADCs 303-1 and 303-2.

During a period from the time t3-5 to a time t3-6, the signals PMRST1 and PMRST2 are Hi, and the reset transistor 2008-1 and the reset transistor 2008-2 are turned ON. A gate voltage of the first amplification transistor 2009-1 and a gate voltage of the second amplification transistor 2009-2 are reset with the power source MVDD.

During a period from a time t3-7 to a time t3-8, the signal WR_A1 and the signal WR_A2 (collectively illustrated as WR_A* in FIG. 5C) are Hi, and the switch 2004-1 and a switch 2004-2 are turned ON. The SA signal held in the signal holding unit 2005-1 is read out to the ADC 303-1 via the first amplification transistor 2009-1. The SA signal held in a signal holding unit 2005-2 is read out to the ADC 303-2 via the second amplification transistor 2009-2. In a period from the time t3-8 to a time t3-9, the SA signals are AD-converted by the respective ADCs 303-1 and 303-2.

During a period from the time t3-9 to a time t3-10, the signals PMRST1 and PMRST2 are Hi, and the reset transistors 2008-1 and 2008-2 are turned ON.

The gate voltage of the first amplification transistor 2009-1 and the gate voltage of the second amplification transistor 2009-2 are reset to a voltage corresponding to the power source MVDD.

During a period from a time t3-11 to a time t3-12, the signal WR_AB1 and the signal WR_AB2 (collectively illustrated as WR_AB* in FIG. 5C) are Hi, and the switch 2006-1 and a switch 2006-2 are turned ON. The SAB signal held in the signal holding unit 2007-1 is read out to the ADC 303-1 via the first amplification transistor 2009-1. The SAB signal held in a signal holding unit 2007-2 is read out to the ADC 303-2 via the second amplification transistor 2009-2. In a period from the time t3-12 to the time t3-13, the SAB signals are AD-converted by the respective ADCs 303-1 and 303-2.

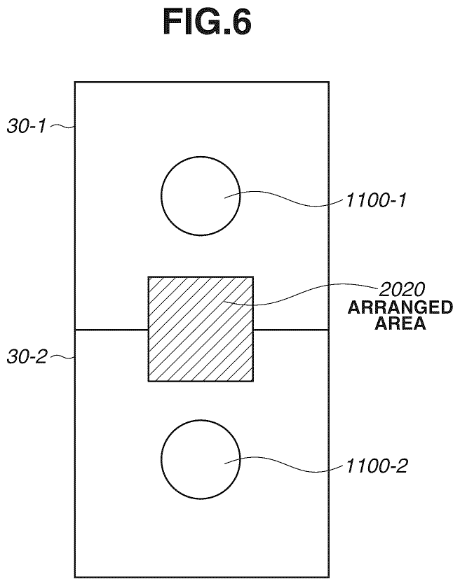

FIG. 6 is a plan view illustrating arrangement positions of the first joint portion 1100-1, the second joint portion 1100-2, and the current source 2020 in the photoelectric conversion device 10 according to the present exemplary embodiment.

In FIG. 6, the first pixel 30-1 and the second pixel 30-2 are arranged adjacent to each other in the vertical direction (e.g., column direction), the first joint portion 1100-1 is arranged in the first pixel 30-1, and the second joint portion 1100-2 is arranged in the second pixel 30-2. Between the first joint portion 1100-1 and the second joint portion 1100-2, a “2020 arranged area” with the current source 2020 arranged therein is provided.

In the present exemplary embodiment, each of the first and second joint portions 1100-1 and 1100-2 is configured by joining a first connection portion provided in a first wiring layer included in the first wiring structure and a second connection portion provided in a second wiring layer included in the second wiring structure. For example, the first connection portion and the second connection portion are conductive members made of copper (Cu), and at a joint surface including a boundary face between the connection portions, insulation members adjacent to the respective first and second connection portions are also connected. The first connection portion and the second connection portion may be connected using Cu—Cu bonding.

In the present exemplary embodiment, the first pixel 30-1 and the second pixel 30-2 are adjacent to each other, but the present exemplary embodiment is not limited to this arrangement. The current source 2020 only needs to be arranged between the joint portions of each group of a plurality of the pixels 30 sharing the current source 2020.

There is generally known a sensor for capturing a color image by providing a color filter on a light incident surface side of each pixel. Each of the pixels of the photoelectric conversion device 10 according to the present exemplary embodiment may be provided with a color filter. In this case, the first pixel 30-1 and the second pixel 30-2 may be provided with respective color filters of the same color, or may be provided with respective color filters different from each other in color.

According to the present exemplary embodiment, it is possible to increase layout efficiency of elements including the current source 2020 and to easily form a layout pattern with the pixel area reduced by sharing the current source 2020 between the two pixels.

Further, it is possible to reduce a peak current by sequentially reading out the pixel signals from the plurality of pixels 30 sharing the current source 2020. In the configuration of the global electronic shutter, since all the pixel signals are read out at a time, a large current may flow at its peck time to cause an electromigration. Further, issues such as an increase in size of a housing can occur because heat generation along with the current becomes large and the heat capacity of the photoelectric conversion device 10 needs to be increased. Further, a reduction in the number of images per unit time that can be captured, or an influence such as a large battery consumption can occur. According to the present exemplary embodiment, such issues are solved because the current peak is less likely to occur by sequentially reading out the pixel signals from the plurality of pixels 30 to the pixel memories 40. A shift in reading timing in a case where the pixel signals of the plurality of pixels 30 are sequentially read out to the pixel memories 40 is sufficiently small, such as about several tens of microseconds.

In addition, the description is given of the case according to the present exemplary embodiment where the current source 2020 is provided in the second semiconductor layer of the memory chip 200, but the current source may be provided in the first semiconductor layer of the pixel chip 100 or in the third semiconductor layer of the signal processing chip 300 depending on the arrangement of the elements in each of the semiconductor layers.

A second exemplary embodiment is an exemplary embodiment in which the number of pixels 30 sharing the current source 2020 is increased to four. Differences from the first exemplary embodiment are mainly described, and common descriptions are omitted.

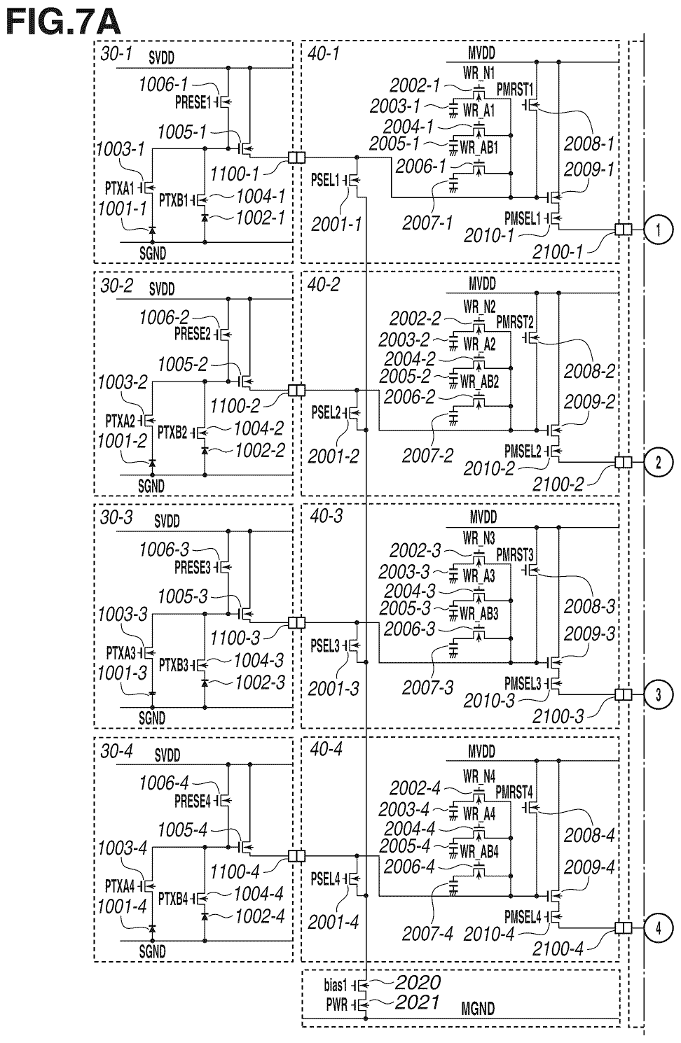

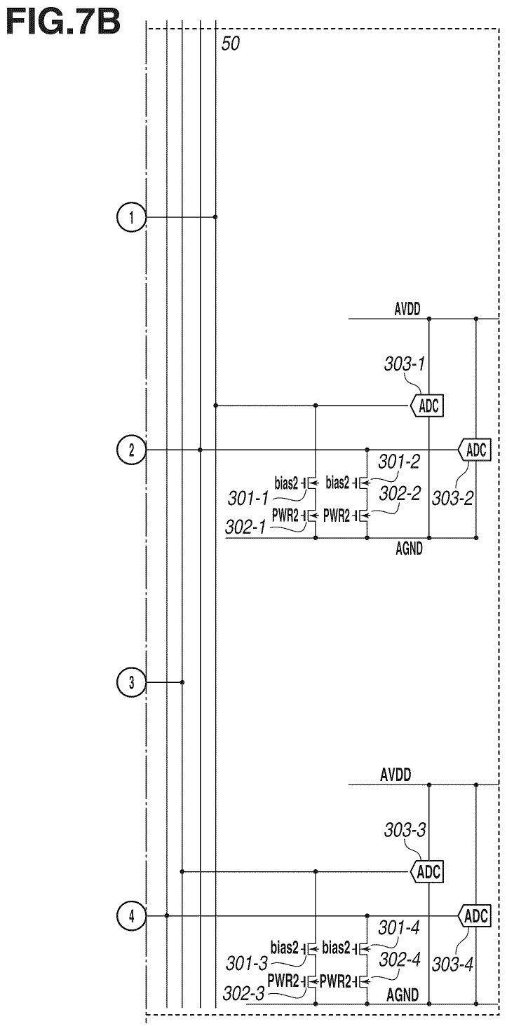

FIGS. 7A and 7B are a circuit diagram of the pixels 30, the pixel memories 40, and the column signal processing circuit 50.

A third pixel 30-3, a fourth pixel 30-4, a third pixel memory 40-3, and a fourth pixel memory 40-4 are added to the configuration of the first exemplary embodiment. Further, an ADC 303-3, an ADC 303-4, a current source 301-3, and a current source 301-4 corresponding to the third pixel memory 40-3 and the fourth pixel memory 40-4 are added to the column signal processing circuit 50.

The source of a selection transistor 2001-3 (third switch) in the third pixel memory 40-3 and the source of a selection transistor 2001-4 (fourth switch) in the fourth pixel memory 40-4 are connected with the drain of the current source 2020. The current source 2020 is used as a common current source load to the first amplification transistor 2009-1, the second amplification transistor 2009-2, a third amplification transistor 2009-3, and a fourth amplification transistor 2009-4, respectively corresponding to the first pixel 30-1 to the fourth pixel 30-4.

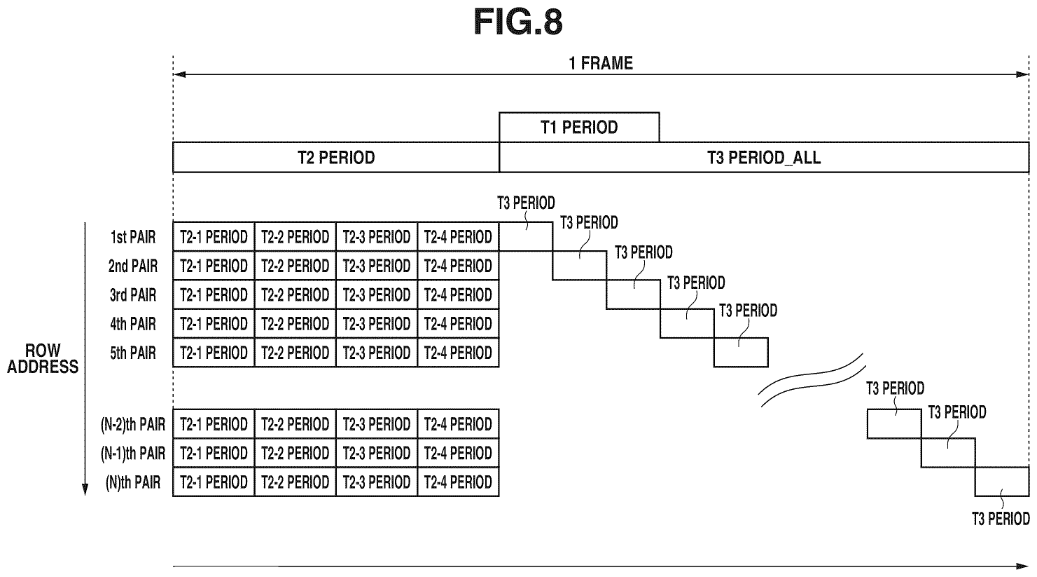

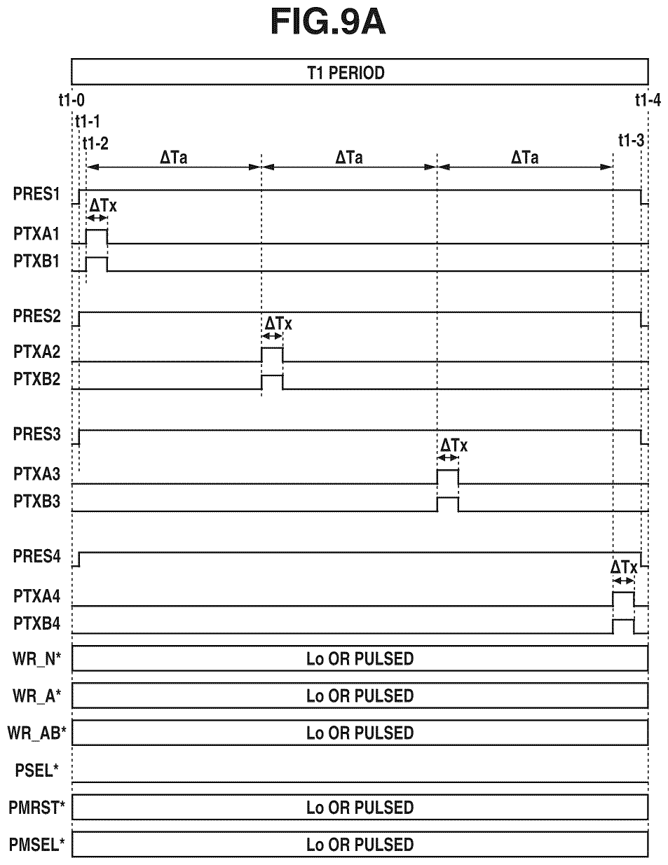

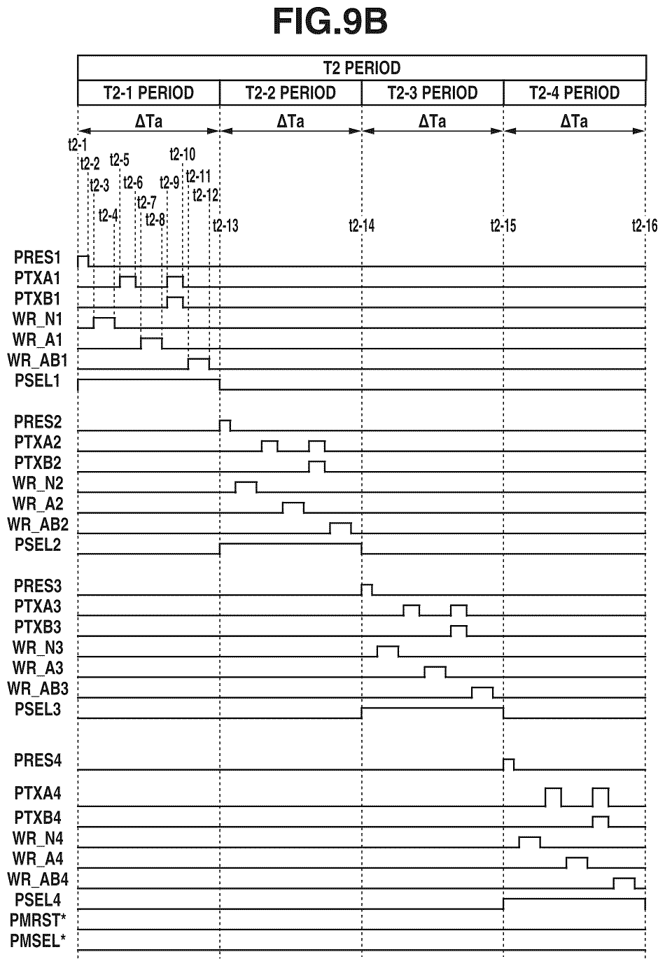

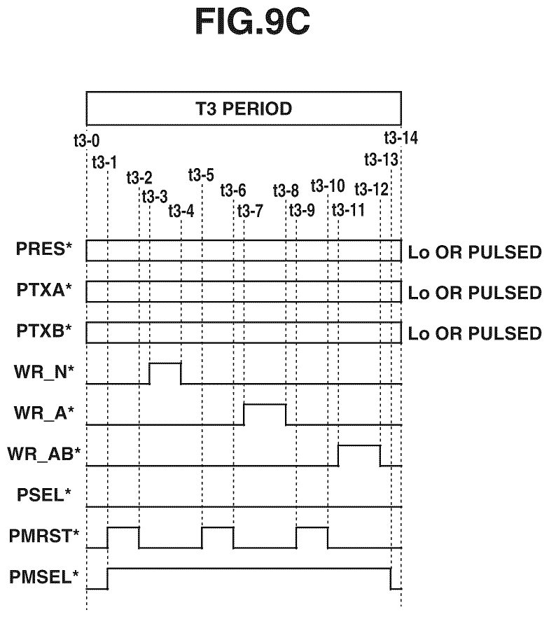

With reference to FIGS. 8, 9A, 9B, and 9C, operation of the present exemplary embodiment will be described.

With reference to FIG. 8, the relationship between the T1 period, the T2 period, and the T3 period according to the present exemplary embodiment will be described.

The second exemplary embodiment is different from the first exemplary embodiment in that the T2 period includes the T2-1 period, the T2-2 period, a T2-3 period, and a T2-4 period. Similar to the first exemplary embodiment, the T3 period_all is a collective term including the plurality of T3 periods.

In the present exemplary embodiment, during the T3 period, the signals of four pixels are read out from the pixel memories 40 to the column signal processing circuit 50 at a time. Thus, when the pixels sharing the current source 2020 are four pixels in different rows, in a case where the number of rows of the pixels 30 is N, the T3 period is repeated N/4 times in the T3 period_all. At this time, the pixels sharing the current source may be arranged in the horizontal direction (row direction). In this case, the number of times of repeating the T3 period increases. The number of times of repeating the T3 period can be reduced by increasing the number of pixels 30 in a group (pair) of the pixels 30 from which the signals are read from the pixel memories 40 to the corresponding column signal processing circuit 50 at a time.

FIGS. 9A and 9B are pulse diagrams respectively illustrating the T1 period and the T2 period. The diagram for the T3 period is the same as that in the first exemplary embodiment, and thus descriptions thereof are omitted.

The T1 period in FIG. 9A is different from that of the first exemplary embodiment in that photodiode reset operations for the third pixel 30-3 and the fourth pixel 30-4 are sequentially performed in addition to the reset operations for the first pixel 30-1 and the second pixel 30-2 during a period from a time t1-0 to a time t1-4.

Similar to the first exemplary embodiment, after the period ΔTa has elapsed from the timing at which the signals PTXA1 and PTXB1 become Hi, which are the photodiode reset operations for the first pixel 30-1, the signals PTXA2 and PTXB2 for the second pixel 30-2 become Hi. At a timing after the period ΔTa has elapsed therefrom, signals PTXA3 and PTXB3 for the third pixel 30-3 become Hi, and signals PTXA4 and PTXB4 for the fourth pixel 30-4 become Hi after the period ΔTa has further elapsed therefrom.

Similar to the first exemplary embodiment, the signals PTXA1, PTXB1, PTXA2, and PTXB2 are Hi during the period ΔTx, and then become Lo.

Similar to the first exemplary embodiment, a phase difference is provided between the signals PTXA1 and PTXA2 and between the signals PTXB1 and PTXB2 for the respective pixels to match the accumulation time periods of the photodiodes. In a case where the accumulation time periods are not matched based on the driving timings, an accumulation time period difference may be corrected in the chip or outside the chip.

During the time period from the time T1-0 to the time T1-4, a signal PSEL* is fixed to Lo. On the other hand, the T1 period and the T3 period may overlap, and signals WR_N*, WR_A*, WR_AB*, PMRST*, and PMSEL* are fixed to Lo or pulsed.

The difference in the T2 period in FIG. 9B from that in the first exemplary embodiment is that the T2-3 period and the T2-4 period are included in sequence after the T2-2 period. In the present exemplary embodiment, the current source 2020 is shared among the first pixel 30-1, the second pixel 30-2, the third pixel 30-3, and the fourth pixel 30-4. This is because the signals of the first pixel 30-1, the second pixel 30-2, the third pixel 30-3, and the fourth pixel 30-4 are sequentially written in the first pixel memory 40-1, the second pixel memory 40-2, the third pixel memory 40-3, and the fourth pixel memory 40-4, respectively. Details of the operations are not described because the operations are similar to those of the first exemplary embodiment.

Operations performed during the T3 period are the same as those illustrated in FIG. 5C according to the first exemplary embodiment. In the first exemplary embodiment, the signals of the first pixel memory 40-1 and the second pixel memory 40-2 are read out to the column signal processing circuit 50 at a time. However, in the present exemplary embodiment, signals of the first pixel memory 40-1, the second pixel memory 40-2, the third pixel memory 40-3, and the fourth pixel memory 40-4 are read out to the column signal processing circuit 50 at a time.

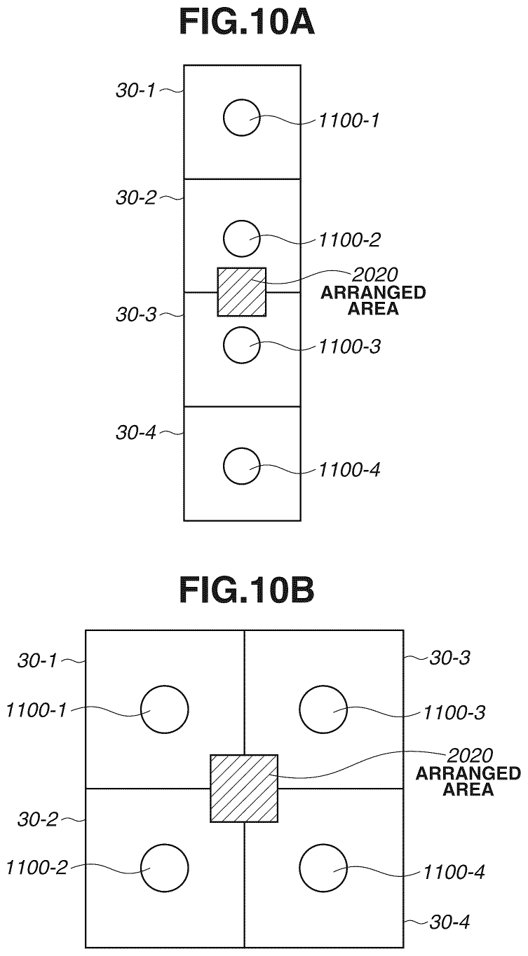

FIGS. 10A and 10B are plan views each illustrating arrangement positions of the first joint portion 1100-1, the second joint portion 1100-2, a third joint portion 1100-3, and a fourth joint portion 1100-4 and the current source 2020 according to the present exemplary embodiment.

FIG. 10A is a diagram illustrating the pixels 30 sharing the current source 2020 arranged in a vertical direction (column direction). The current source 2020 is arranged between the second joint portion 1100-2 of the second pixel 30-2 and the third joint portion 1100-3 of the third pixel 30-3.

FIG. 10B is a diagram illustrating a case where the current source 2020 is shared by a total of four pixels including two pixels in the vertical direction and two pixels in the horizontal direction. The first pixel 30-1 and the third pixel 30-3 are arranged in the horizontal direction, the first pixel 30-1 and the second pixel 30-2 are arranged in the vertical direction, and the third pixel 30-3 and the fourth pixel 30-4 are arranged in the vertical direction. The first pixel 30-1 includes the first joint portion 1100-1, and the second pixel 30-2 includes the second joint portion 1100-2. The third pixel 30-3 includes the third joint portion 1100-3, and the fourth pixel 30-4 includes the fourth joint portion 1100-4. The current source 2020 is arranged between the first joint portion 1100-1 and the fourth joint portion 1100-4, and between the second joint portion 1100-2 and the third joint portion 1100-3.

In both of FIGS. 10A and 10B, the current source 2020 is arranged between two or more joint portions. In this case, in a case where the photoelectric conversion device 10 according to the present exemplary embodiment is a device capable of capturing a color image, the pixels 30 sharing the current source 2020 may be the pixels 30 for a same color, or for different colors. Alternatively, the four pixels 30 arranged in a Bayer array may share the one current source 2020.

In the present exemplary embodiment, the number of pixels sharing the current source 2020 is increased to four, which is different from that in the first exemplary embodiment, but the number of pixels sharing the current source 2020 is not limited to four. For example, a configuration in which nine pixels or 16 pixels share the current source 2020 may also be employed.

In the present exemplary embodiment, similar to the first exemplary embodiment, it is possible to reduce the restriction on the layout of the elements constituting the pixels by sharing the current source 2020 among the plurality of pixels 30, and to easily form a layout pattern with the pixel area reduced. Further, it is possible to reduce the peak current by sequentially reading the pixel signals from the plurality of pixels 30 sharing the current source 2020.

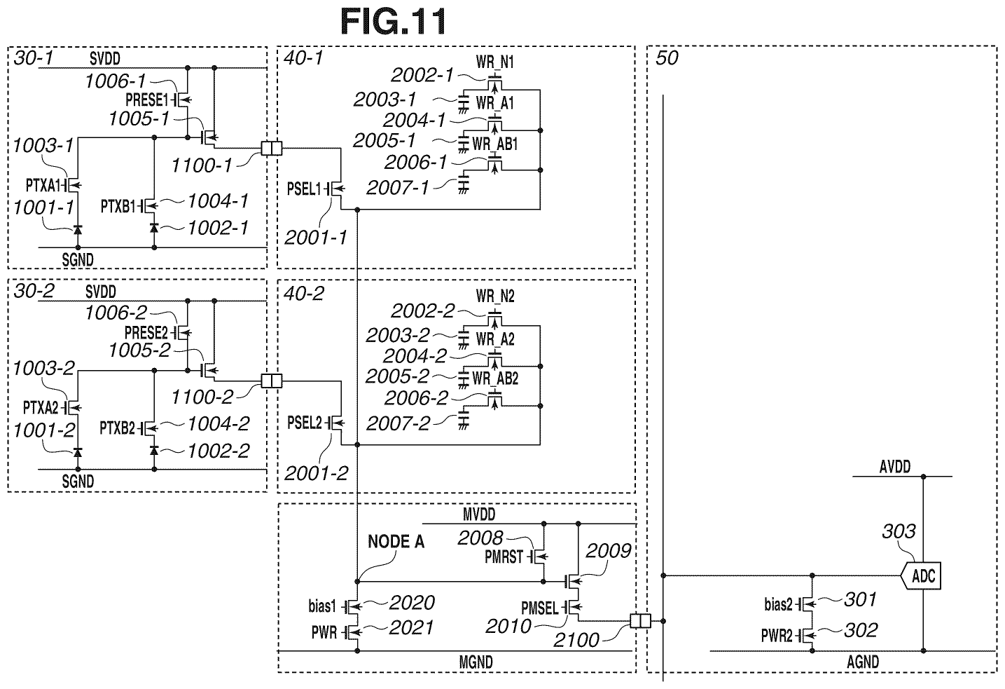

With reference to FIGS. 11 to 13, a photoelectric conversion device according to a third exemplary embodiment will be described. FIG. 11 is a circuit diagram of the pixels 30, the pixel memories 40, and the column signal processing circuit 50. In the photoelectric conversion device 10 according to the first and second exemplary embodiments, the pixel memories 40 respectively include the amplification transistors 2009-1 and 2009-2, or the amplification transistors 2009-1, 2009-2, 2009-3, and 2009-4. In a photoelectric conversion device 10 according to the present exemplary embodiment, an amplification transistor 2009 is connected to and shared among the plurality of pixel memories 40.

In the photoelectric conversion device 10 according to the present exemplary embodiment, the source of the selection transistor 2001-1 in the first pixel memory 40-1 and the source of the selection transistor 2001-2 in the second pixel memory 40-2 are connected to the drain of the current source 2020. When the drain of the current source 2020 is defined as a node A, one terminal of each of the switch 2002-1, the switch 2004-1, and the switch 2006-1 in the first pixel memory 40-1 is connected to the node A. Further, one terminal of each of the switch 2002-2, the switch 2004-2, and the switch 2006-2 in the second pixel memory 40-2 is connected to the node A.

Further, a reset transistor 2008 is connected to the node A in series with the power source MVDD, and the gate of the amplification transistor 2009 is also connected to the node A. The drain of the amplification transistor 2009 is connected to the power source MVDD, and the source thereof is connected to the drain of a selection transistor 2010. The source of the selection transistor 2010 is connected to the input of an ADC 303 in the column signal processing circuit 50 and to the drain of a current source 301 via a joint portion 2100. Between the source of the current source 301 and the ground AGND, a switch 302 is connected in series. By providing the switch 302, it is possible to reduce the power consumption by turning OFF the switch 302 when the signals are not read from the pixel memories 40.

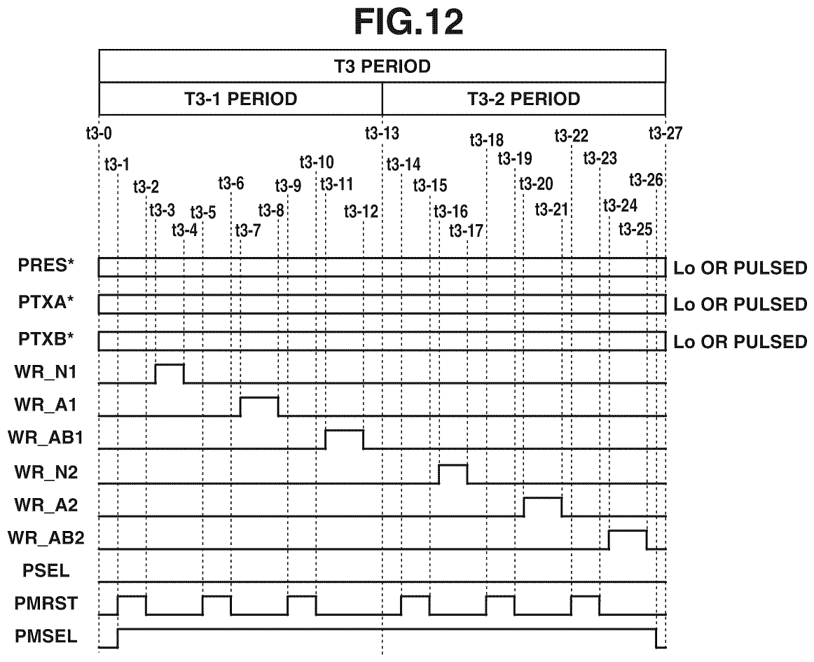

With reference to FIG. 12, operations of the photoelectric conversion device 10 according to the present exemplary embodiment during the T3 period will be described. The operations during the T1 period and the T2 period are the same as those illustrated in FIGS. 5A and 5B described in the first exemplary embodiment, and thus descriptions thereof are omitted.

The period from a time t3-0 to a time t3-13 is defined as a T3-1 period, and the period from the time t3-13 to a time t3-27 is defined as a T3-2 period. The T3-1 period is a period in which a signal from the first pixel memory 40-1 is read out to the column signal processing circuit 50, and the T3-2 period is a period in which a signal from the second pixel memory 40-2 is read out to the column signal processing circuit 50.

During the period from the time t3-1 to the time T3-26, a signal PMSEL is Hi. The selection transistor 2010 is turned ON, and the source of the amplification transistor 2009 is connected to the input of the ADC 303 via the joint portion 2100.

During the period from the time t3-1 to the time t3-2, a signal PMRST is Hi, the reset transistor 2008 is turned ON, and the node A is reset with the power source MVDD.

During the period from the time t3-3 to the time t3-4, the signal WR_N1 is Hi, the switch 2002-1 is turned ON, and the N signal held in the signal holding unit 2003-1 is read out to the node A. The N signal read out to the node A is input to the ADC 303 via the amplification transistor 2009.

In the period from the time t3-4 to the time t3-5, the N signal is AD-converted by the ADC 303.

During the period from the time t3-5 to the time t3-6, the signal PMRST is Hi. The node A is reset with the power source MVDD again.

During the period from the time t3-7 to the time t3-8, the signal WR_A1 is Hi. The switch 2004-1 is turned ON, and the SA signal held in the signal holding unit 2005-1 is read out to the node A.

In the period from the time t3-8 to the time t3-9, the SA signal read out to the ADC 303 via the amplification transistor 2009 is AD-converted.

During the period from the time t3-9 to the time t3-10, the signal PMRST is Hi. The node A is reset with the power source MVDD again.

During the period from the time t3-11 to the time t3-12, the signal WR_AB1 is Hi. The switch 2006-1 is turned ON, and the SAB signal held in the signal holding unit 2007-1 is read out to the node A.

In the period from the time t3-12 to the time t3-13, the SAB signal read out to the ADC 303 via the amplification transistor 2009 is AD-converted.

During the period from the time t3-14 to the time t3-15, the signal PMRST is Hi. The node A is reset with the power source MVDD.

During the period from the time t3-16 to the time t3-17, the signal WR_N2 is Hi. The switch 2002-2 is turned ON, and the N signal held in the signal holding unit 2003-2 is read out to the node A.

In the period from the time t3-17 to the time t3-18, the N signal read out to the ADC 303 via the amplification transistor 2009 is AD-converted.

During the period from the time t3-18 to the time t3-19, the signal PMRST is Hi. The node A is reset with the power source MVDD again.

During the period from the time t3-20 to the time t3-21, the signal WR_A2 is Hi. The switch 2004-2 is turned ON, and the SA signal held in the signal holding unit 2005-2 is read out to the node A.

In the period from the time t3-21 to the time t3-22, the SA signal read out to the ADC 303 via the amplification transistor 2009 is AD-converted.

During the period from the time t3-22 to the time t3-23, the signal PMRST is Hi. The node A is reset with the power source MVDD again.

During the period from the time t3-24 to the time t3-25, the signal WR_AB2 is Hi. The switch 2006-2 is turned ON, and the SAB signal held in the signal holding unit 2007-2 is read out to the node A.

In the period from the time t3-25 to the time t3-26, the SAB signal read out to the ADC 303 via the amplification transistor 2009 is AD-converted.

At the time t3-26, when the signal PMSEL becomes Lo, and the selection transistor 2010 is turned OFF, the electrical connection between the amplification transistor 2009 and the ADC 303 is cut off.

In the present exemplary embodiment, as described above, the reset transistor 2008, the amplification transistor 2009, and the selection transistor 2010 in addition to the current source 2020 are shared between the first pixel memory 40-1 and the second pixel memory 40-2. With this configuration, the layout efficiency of the photoelectric conversion device 10 according to the present exemplary embodiment can be improved more than that according to the first and second exemplary embodiments.

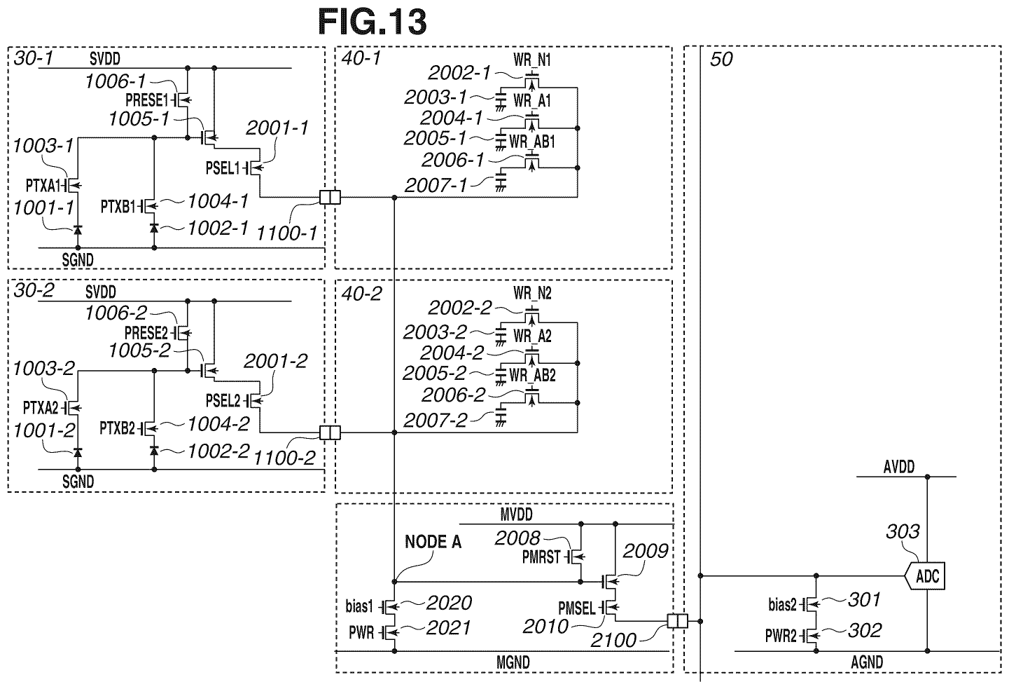

As a modification example of the third exemplary embodiment, FIG. 13 illustrates a circuit diagram in a case where the selection transistor 2001-1 and the selection transistor 2001-2 are arranged in the first semiconductor layer with the photodiodes formed therein. Operations thereof are similar to those of the circuit illustrated in FIG. 11. Whether to arrange the selection transistor 2001-1 and the selection transistor 2001-2 in the first semiconductor layer or in the second semiconductor layer with the pixel memories 40 arranged therein can be appropriately selected from a perspective of improving performance of an apparatus, such as balance of element areas, and magnitude of heat generation.

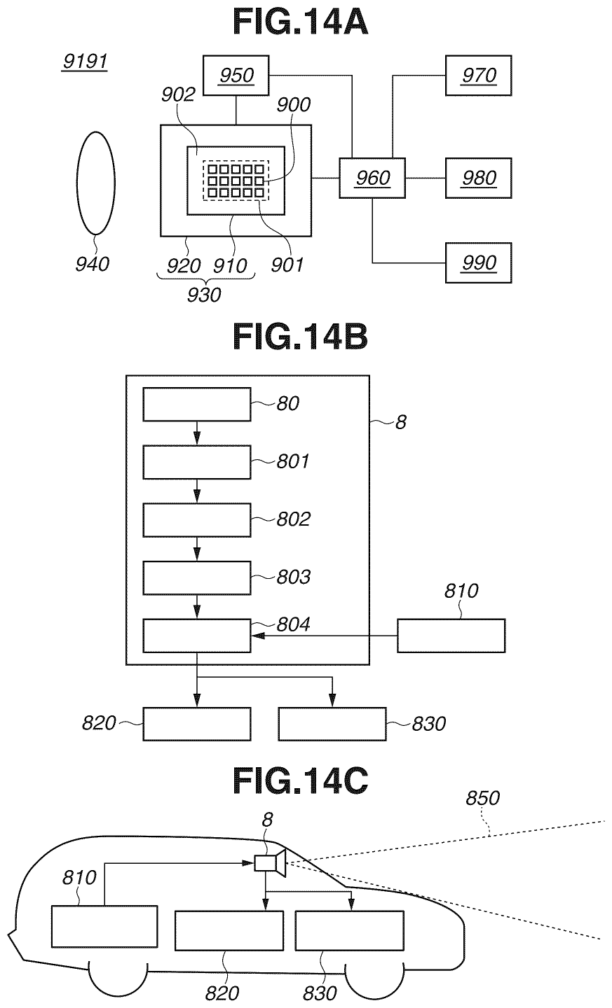

Any of the first to third exemplary embodiments can be applied to a fourth exemplary embodiment. FIG. 14A is a block diagram schematically illustrating an apparatus 9191 including a semiconductor apparatus 930 according to the present exemplary embodiment. The photoelectric conversion device 10 according to each of the above-described exemplary embodiments can be used for the semiconductor apparatus 930. The apparatus 9191 including the semiconductor apparatus 930 will be described in detail. The semiconductor apparatus 930 can include, in addition to a semiconductor device 910, a package 920 containing the semiconductor device 910. The package 920 can include a base member to which the semiconductor device 910 is fixed, and a cover member, such as a glass plate, facing the semiconductor device 910. Further, the package 920 can include a connection member, such as a bonding wire or a bump, for connecting a terminal provided on the base member with a terminal provided on the semiconductor device 910.

The apparatus 9191 can include at least any of an optical device 940, a control device 950, a processing device 960, a display device 970, a storage device 980, and a mechanical device 990. The optical device 940 is used for the semiconductor apparatus 930. The optical device 940 includes an optical system such as a lens, a shutter, and a mirror for guiding light to the semiconductor apparatus 930. The control device 950 controls the semiconductor apparatus 930. The control device 950 is a semiconductor device such as an application specific integrated circuit (ASIC).

A portion including at least any of the processing device 960, the display device 970, the storage device 980, and the mechanical device 990 is a processing unit having a function of processing a signal from the semiconductor apparatus 930 to generate an image.

The processing device 960 processes a signal output from the semiconductor apparatus 930. The processing device 960 is a semiconductor device such as a central processing unit (CPU) or an ASIC for constituting an analog front end (AFE) or a digital front end (DFE). The display device 970 is an electroluminescence (EL) display device or a liquid crystal display device for displaying information (image) obtained by the semiconductor apparatus 930. The storage device 980 is a magnetic device or a semiconductor device that stores the information (image) obtained by the semiconductor apparatus 930. The storage device 980 is a volatile memory such as a static random access memory (SRAM) and a dynamic random access memory (DRAM), or a non-volatile memory such as a flash memory and a hard disk drive.

The mechanical device 990 includes a movable part or a propulsion part, such as a motor and an engine. The apparatus 9191 displays a signal output from the semiconductor apparatus 930 on the display device 970, and transmits the signal to the outside via a communication device (not illustrated) included in the apparatus 9191. Thus, it is desirable that the apparatus 9191 further includes the storage device 980 and the processing device 960 separately from a storage circuit and a calculation circuit included in the semiconductor apparatus 930. The mechanical device 990 may be controlled based on a signal output from the semiconductor apparatus 930.

The apparatus 9191 can be suitably used for electronic apparatuses such as information terminals (e.g., smartphone and wearable terminal) and cameras (e.g., lens-interchangeable type cameras, compact cameras, video cameras, and monitoring cameras), each having an image capturing function. The mechanical device 990 in a camera can drive components used for zooming, focusing, and shutter operation in the optical device 940. Further, the mechanical device 990 in the camera can move the semiconductor apparatus 930 for image stabilization operation.

The apparatus 9191 can be a transport apparatus such as a wheeled vehicle, a ship, and a flight vehicle. The mechanical device 990 in the transport apparatus can be used as a moving apparatus. The apparatus 9191 as the transport apparatus is suitably used for an apparatus for transporting the semiconductor apparatus 930 and an apparatus for providing assistance and/or automatization of driving (steering) of the transport apparatus using the image capturing function. The processing device 960 for providing assistance and/or automatization of driving (steering) of the transport apparatus can perform processing for operating the mechanical device 990 as the moving apparatus based on the information obtained by the semiconductor apparatus 930. Alternatively, the apparatus 9191 may be a medical device such as an endoscope, a measurement device such as a distance measuring sensor, an analysis device such as an electron microscope, an office machine such as a copying machine, and an industrial machine such as a robot.

According to the exemplary embodiments described above, good pixel characteristics can be obtained. Accordingly, it is possible to increase value of a semiconductor device. The term “to increase value” herein corresponds to at least any of adding functions, improving performance, improving characteristics, improving reliability, improving production yields, reducing environmental loads, reducing costs, downsizing, and weight saving.

Thus, when the semiconductor apparatus 930 according to the present exemplary embodiment is used for the apparatus 9191, the value of the apparatus 9191 can also be increased. For example, in a case where the semiconductor apparatus 930 is mounted on the transport apparatus to capture an image outside the transport apparatus or to measure an external environment, it is possible to obtain an excellent performance. Thus, in producing and selling the transport apparatus, if it is determined that the semiconductor apparatus 930 according to the present exemplary embodiment is to be mounted on the transport apparatus, it is advantageous to enhance the performance of the transport apparatus. In particular, the semiconductor apparatus 930 is suitably used for the transport apparatus that provides driving assistance and/or automatization of driving of the transport apparatus using the information obtained by the semiconductor apparatus 930.

With reference to FIGS. 14B and 14C, a photoelectric conversion system and a movable object according to the present exemplary embodiment will be described.

FIG. 14B is a block diagram illustrating an example of the photoelectric conversion system related to a car-mounted camera. A photoelectric conversion system 8 includes a photoelectric conversion device 80. The photoelectric conversion device 80 is the photoelectric conversion device 10 (image capturing apparatus) described in any of the exemplary embodiments described above. The photoelectric conversion system 8 includes an image processing unit 801 and a parallax acquisition unit 802. The image processing unit 801 performs image processing on a plurality of pieces of image data captured by the photoelectric conversion device 80. The parallax acquisition unit 802 calculates a parallax (i.e., phase difference between parallax images) from the plurality of pieces of image data captured by the photoelectric conversion system 8. Further, the photoelectric conversion system 8 includes a distance acquisition unit 803 configured to calculate a distance to an object based on the calculated parallax, and a collision determination unit 804 configured to determine whether there is a possibility of collision based on the calculated distance. In the present exemplary embodiment, the parallax acquisition unit 802 and the distance acquisition unit 803 are examples of a distance information acquisition unit that acquires distance information to the object. In other words, the distance information includes information about a parallax, a defocus amount, a distance to an object, and the like. The collision determination unit 804 may determine the possibility of collision using any of these pieces of information in the distance information. The distance information acquisition unit may be implemented by exclusively designed hardware components, or software modules. The distance information acquisition unit may be implemented by a Field Programmable Gate Array (FPGA) or an ASIC, or a combination thereof.

The photoelectric conversion system 8 is connected with a vehicle information acquisition apparatus 810, and can acquire vehicle information such as a vehicle speed, a yaw rate, and a steering angle. Further, an electronic control unit (ECU) 820 serving as a control unit for outputting a control signal to generate a braking force on the wheeled vehicle based on a determination result of the collision determination unit 804 is connected to the photoelectric conversion system 8. The photoelectric conversion system 8 is also connected with an alarming apparatus 830 for issuing an alarm to a driver based on a determination result of the collision determination unit 804. For example, in a case where the possibility of collision is high as the determination result of the collision determination unit 804, the ECU 820 controls the wheeled vehicle to avoid collision or reduce damage by applying brakes, releasing an accelerator pedal, reducing output of engine power, or the like. The alarming apparatus 830 gives a warning to the driver (user) by giving an alarm by sound or the like, displaying alarm information on a screen of a car navigation system, and/or giving vibrations to a seat belt or a steering wheel.

In the present exemplary embodiment, the photoelectric conversion system 8 captures an image around the wheeled vehicle, for example, in front of or behind the wheeled vehicle.

FIG. 14C illustrates the photoelectric conversion system 8 in the case of capturing an image in front of the vehicle (imaging range 850). The vehicle information acquisition apparatus 810 transmits an instruction to the photoelectric conversion system 8 or the photoelectric conversion device 80. With this configuration, it is possible to improve accuracy of distance measurement.

In the above-described exemplary embodiment, the example to control the wheeled vehicle not to collide with another wheeled vehicle is described. However, it is also possible to control a wheeled vehicle to perform automated driving so as to follow another wheeled vehicle, or to perform automated driving so as not to run out of a traffic lane. Further, the photoelectric conversion system 8 is applicable to, for example, a movable object (movable apparatus) such as a ship, an aircraft, and an industrial robot, not limited to the wheeled vehicle such as a car. In addition, not limited to the movable object, the photoelectric conversion system 8 is also applicable to various apparatuses that use object recognition, such as an intelligent transport system (ITS).

The exemplary embodiments described above can be appropriately modified without departing from the technical idea. The disclosure of the present specification includes not only what is described in the present specification but also all matters that can be grasped from the present specification and the drawings attached to the present specification. The disclosure herein also includes a complementary set of concepts described herein. More specifically, if “A is larger than B” is described in the present specification, even if a description that “A is not larger than B” is omitted, it can be said that the present specification discloses the description that “A is not larger than B”. This is because, in a case where the description “A is larger than B” is described, a case where “A is not larger than B” is assumed to be considered.

According to the present disclosure, it is possible to reduce the restriction on the layout of the pixels.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-090291, filed Jun. 3, 2024, which is hereby incorporated by reference herein in its entirety.

What is claimed is:

1. A photoelectric conversion device comprising:
a plurality of pixels including a first pixel and a second pixel,
wherein each of the plurality of pixels includes:
a first semiconductor layer including a photoelectric conversion unit, and a first readout circuit configured to read out a signal obtained based on photoelectric conversion by the photoelectric conversion unit; and
a second semiconductor layer including a memory configured to hold a voltage corresponding to the signal, and an output circuit configured to output the voltage held in the memory, the first semiconductor layer and the second semiconductor layer being layered,
wherein the first readout circuit of the first pixel includes a first amplification transistor,
wherein the first readout circuit of the second pixel includes a second amplification transistor,
wherein the first amplification transistor is connected to a first current source via a first switch,
wherein the second amplification transistor is connected to the first current source via a second switch, and
wherein the first amplification transistor and the second amplification transistor share the first current source.

2. The photoelectric conversion device according to claim 1, wherein the first current source is arranged in the second semiconductor layer.

3. The photoelectric conversion device according to claim 1,
wherein the plurality of pixels includes a third pixel and a fourth pixel,
wherein the first readout circuit of the third pixel includes a third amplification transistor,
wherein the first readout circuit of the fourth pixel includes a fourth amplification transistor,
wherein the third amplification transistor is connected to the first current source via a third switch,
wherein the fourth amplification transistor is connected to the first current source via a fourth switch, and
wherein the first amplification transistor, the second amplification transistor, the third amplification transistor, and the fourth amplification transistor share the first current source.

4. The photoelectric conversion device according to claim 1, further comprising:
a first joint portion configured to electrically connect the first readout circuit of the first pixel and the memory; and
a second joint portion configured to electrically connect the first readout circuit of the second pixel and the memory,
wherein the first current source is arranged between the first joint portion and the second joint portion in planar view.

5. The photoelectric conversion device according to claim 1,
wherein the first pixel and the second pixel are provided with respective color filters, and
wherein the color filter provided on the first pixel and the color filter provided on the second pixel are filters with a same color.

6. The photoelectric conversion device according to claim 1,
wherein the first pixel and the second pixel are provided with respective color filters, and
wherein the color filter provided on the first pixel and the color filter provided on the second pixel are filters with different colors.

7. The photoelectric conversion device according to claim 1, wherein the first switch is arranged in the first semiconductor layer.

8. The photoelectric conversion device according to claim 1, wherein the first switch and the second switch operate in such a manner that when one of the first switch and the second switch is ON, the other is OFF.

9. The photoelectric conversion device according to claim 3, wherein the first switch, the second switch, the third switch, and the fourth switch operate in such a manner that when one of the first switch, the second switch, the third switch, and the fourth switch is ON, the remaining three switches are OFF.

10. The photoelectric conversion device according to claim 1, wherein a third semiconductor layer including a second readout circuit configured to read out the signal corresponding to the voltage held in the memory is further layered on the second semiconductor layer.

11. The photoelectric conversion device according to claim 4, further comprising:
a first chip; and
a second chip layered on the first chip,
wherein the first chip includes the first semiconductor layer, and a first wiring structure electrically connected with the photoelectric conversion unit and the first readout circuit,
wherein the second chip includes the second semiconductor layer, and a second wiring structure electrically connected with the memory and the output circuit, and
wherein the first joint portion is configured by joining a first connection portion provided on a first wiring layer included in the first wiring structure and a second connection portion provided on a second wiring layer included in the second wiring structure.

12. The photoelectric conversion device according to claim 11, further comprising a third chip,
wherein the third chip includes a third semiconductor layer including a second readout circuit configured to read out the signal corresponding to the voltage held in the memory, and a third wiring structure electrically connected with the second readout circuit.

13. The photoelectric conversion device according to claim 12, wherein a signal that passes through a wiring line connected between the first chip and the second chip passes through a wiring line of the third chip.

14. The photoelectric conversion device according to claim 1, wherein the first switch and the second switch are arranged in the second semiconductor layer.

15. The photoelectric conversion device according to claim 1, wherein the first switch and the second switch are arranged in the first semiconductor layer.

16. A photoelectric conversion system comprising:
a photoelectric conversion device including a plurality of pixels including a first pixel and a second pixel,
wherein each of the plurality of pixels includes a first semiconductor layer including a photoelectric conversion unit, and a first readout circuit configured to read out a signal obtained based on photoelectric conversion by the photoelectric conversion unit; and a second semiconductor layer including a memory configured to hold a voltage corresponding to the signal, and an output circuit configured to output the voltage held in the memory, the first semiconductor layer and the second semiconductor layer being layered,
wherein the first readout circuit of the first pixel includes a first amplification transistor,
wherein the first readout circuit of the second pixel includes a second amplification transistor,
wherein the first amplification transistor is connected to a first current source via a first switch,
wherein the second amplification transistor is connected to the first current source via a second switch, and
wherein the first amplification transistor and the second amplification transistor share the first current source; and
a processing unit configured to generate an image using a signal output from the photoelectric conversion device.

17. A movable object comprising:
a photoelectric conversion device including a plurality of pixels including a first pixel and a second pixel,
wherein each of the plurality of pixels includes a first semiconductor layer including a photoelectric conversion unit, and a first readout circuit configured to read out a signal obtained based on photoelectric conversion by the photoelectric conversion unit; and a second semiconductor layer including a memory configured to hold a voltage corresponding to the signal, and an output circuit configured to output the voltage held in the memory, the first semiconductor layer and the second semiconductor layer being layered,
wherein the first readout circuit of the first pixel includes a first amplification transistor,
wherein the first readout circuit of the second pixel includes a second amplification transistor,
wherein the first amplification transistor is connected to a first current source via a first switch,
wherein the second amplification transistor is connected to the first current source via a second switch, and
wherein the first amplification transistor and the second amplification transistor share the first current source,
wherein the movable object includes a control unit configured to control movement of the movable object using a signal output from the photoelectric conversion device.
